(19) United States
(12) Patent Application Publication
(10) Pub. No.: US 2025/0358962 A1
(43) Pub. Date: Nov. 20, 2025

(54) COMPOSITE HEAT DISSIPATION MECHANISM

(71) Applicant: COOLER MASTER CO., LTD., Taipei City (TW)

(72) Inventors: TUNG-YANG SHIEH, Taipei City (TW); CHIU-YU YEH, Taipei City (TW)

(73) Assignee: COOLER MASTER CO., LTD., Taipei City (TW)

(21) Appl. No.: 19/169,097

(22) Filed: Apr. 3, 2025

(30) Foreign Application Priority Data
May 15, 2024 (TW) 113204943

(51) Int. Cl. H05K 7/20

(52) U.S. Cl. CPC H05K 7/20272; H05K 7/20154; H05K 7/20336

(57) ABSTRACT

A composite heat dissipation mechanism is provided for dissipating heat from heat sources. The mechanism includes an air-cooling heat dissipation assembly and a liquid-cooling heat dissipation assembly. The air-cooling heat dissipation assembly includes an airflow generator with a first air outlet, and a first heat dissipation fin disposed adjacent to the first air outlet and thermally coupled to the heat sources. The liquid-cooling heat dissipation assembly includes a heat-conducting flow pipe thermally coupled to the first heat dissipation fin and configured to accommodate a cooling fluid, and a fluid driver in communication with the heat-conducting flow pipe to form a circulation flow path. The fluid driver is configured to drive the cooling fluid to circulate within the circulation flow path.

### RELATED APPLICATIONS

This US application claims the benefit of priority to Taiwan application No. 113204943, filed on May 15, 2024, of which is incorporated herein by reference in its entirety.

### TECHNICAL FIELD

The disclosure relates to a composite heat dissipation mechanism, in particular to a composite heat dissipation mechanism having an air-cooling heat dissipation assembly and a liquid-cooling heat dissipation assembly.

### BACKGROUND

As processor performance improves, the heat generated by the processor also increases. If the generated heat accumulates within the electronic device, the performance and lifespan of the electronic device may be reduced. Thus, the demand for efficient heat dissipation has been increased over time as the performance of electronic devices, notably in computers, has continued to improve.

Conventional heat dissipation mechanisms primarily use either air cooling or liquid cooling. The former utilizes a fan to blow air onto heat dissipation fins thermally coupled to a heat source, thereby dissipating the heat generated by the heat source. The latter employs a circulating liquid cooling system composed of a water block, radiator, and pump, where a cooling fluid absorbs heat from the heat source via the water block. However, any of these two cooling techniques may only be effective for dissipating heat from a single heat source; with multiple heat sources, the effectiveness of heat dissipation by either air cooling or liquid cooling remains room for improvement. Therefore, there is still a need to improve cooling solutions for electronic devices, particularly those with multiple heat sources.

### SUMMARY

Aspects of the disclosure provide a composite heat dissipation mechanism. The composite heat dissipation mechanism is configured to dissipate heat from heat sources. The composite heat dissipation mechanism includes an air-cooling heat dissipation assembly and a liquid-cooling heat dissipation assembly. The air-cooling heat dissipation assembly includes an airflow generator and a first heat dissipation fin. The airflow generator has a first air outlet. The first heat dissipation fin is disposed adjacent to the first air outlet of the airflow generator and is thermally coupled to the heat sources. The liquid-cooling heat dissipation assembly includes a heat-conducting flow pipe and a fluid driver. The heat-conducting flow pipe is thermally coupled to the first heat dissipation fin and is configured to accommodate a cooling fluid. The fluid driver is in communication with the heat-conducting flow pipe to form a circulation flow path and is configured to drive the cooling fluid to circulate within the circulation flow path.

In one embodiment, the air-cooling heat dissipation assembly further includes a heat pipe, a first end of the heat pipe is thermally coupled to the first heat dissipation fin, and a second end of the heat pipe is thermally coupled to the heat sources.

In one embodiment, the heat-conducting flow pipe is thermally coupled to the heat sources.

In one embodiment, the airflow generator has a second air outlet, the second air outlet being oriented in a direction different from that of the first air outlet, and the air-cooling heat dissipation assembly further includes a second heat dissipation fin located adjacent to the second air outlet.

In one embodiment, the heat-conducting flow pipe is thermally coupled to the second heat dissipation fin.

In one embodiment, the heat-conducting flow pipe is arranged surrounding the airflow generator.

Another aspect of the disclosure provides an electronic device includes at least one heat source group, at least one air-cooling heat dissipation assembly, and a liquid-cooling heat dissipation assembly. The air-cooling heat dissipation assembly includes an airflow generator and a first heat dissipation fin. The airflow generator has a first air outlet. The first heat dissipation fin is disposed adjacent to the first air outlet of the airflow generator and is thermally coupled to the heat source group. The liquid-cooling heat dissipation assembly includes a heat-conducting flow pipe and a fluid driver. The heat-conducting flow pipe is thermally coupled to the first heat dissipation fin and is configured to accommodate a cooling fluid. The fluid driver is in communication with the heat-conducting flow pipe to form a circulation flow path and is configured to drive the cooling fluid to circulate within the circulation flow path.

In one embodiment, the air-cooling heat dissipation assembly further includes at least one first heat pipe, a first end of the first heat pipe is thermally coupled to the first heat dissipation fin, and a second end of the first heat pipe is thermally coupled to the heat source group.

In one embodiment, the heat source group includes two heat sources, the air-cooling heat dissipation assembly includes two air-cooling heat dissipation devices, and the first end of the first heat pipe of each of the two air-cooling heat dissipation devices is respectively thermally coupled to the two heat sources while the second end of the first heat pipe of each of the two air-cooling heat dissipation devices is respectively thermally coupled to the first heat dissipation fin of each of the two air-cooling heat dissipation devices.

In one embodiment, the air-cooling heat dissipation assembly further includes a second heat pipe, a first end of the second heat pipe is thermally coupled to one of the first heat dissipation fin, and a second end of the second heat pipe is thermally coupled to the heat source group.

In one embodiment, the heat-conducting flow pipe is thermally coupled to the heat source group.

In one embodiment, the airflow generator has a second air outlet being oriented in a direction different from that of the first air outlet, and the air-cooling heat dissipation assembly further includes a second heat dissipation fin located adjacent to the second air outlet.

In one embodiment, the heat-conducting flow pipe is thermally coupled to the second heat dissipation fin.

In one embodiment, the heat-conducting flow pipe is arranged surrounding the airflow generator.

Still another aspect of the disclosure provides a liquid-cooling heat dissipation assembly includes a heat-conducting flow pipe thermally coupled to a heat source and configured to accommodate a cooling fluid. The liquid-cooling heat dissipation assembly further includes a fluid driver in fluid communication with the heat-conducting flow pipe and configured to circulate the cooling fluid by a fluid outlet and a fluid inlet. A flow direction of the cooling fluid from the fluid outlet and a flow direction of the cooling fluid to the fluid inlet are different.

In one embodiment, the flow direction of the cooling fluid to the fluid inlet and the flow direction of the cooling fluid from the fluid outlet are opposite.

In one embodiment, the fluid outlet and the fluid inlet are located on the same side of the fluid driver.

In one embodiment, the heat-conducting flow pipe defines a placement plane, and at least one of the fluid outlet and the fluid inlet is not located within the placement plane.

In one embodiment, the fluid driver further includes a driver port for controlling an amount of the cooling fluid.

In one embodiment, the driver port is in fluid communication with the fluid outlet.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 is a perspective view of an electronic device according to an embodiment of the disclosure.

FIG. 2 is an exploded schematic view of the air-cooling heat dissipation assembly in FIG. 1.

FIG. 3 is an exploded schematic view of the heat source region in FIG. 1.

FIG. 4 is a top view of the electronic device in FIG. 1, illustrating the heat dissipation paths.

FIG. 5 is a perspective view of the liquid-cooling heat dissipation assembly in FIG. 1.

### DETAILED DESCRIPTION

Detailed descriptions and technical contents of the disclosure are illustrated below in conjunction with the accompanying drawings. However, it is to be understood that the descriptions and the accompanying drawings disclosed herein are merely illustrative and exemplary and not intended to limit the scope of the disclosure.

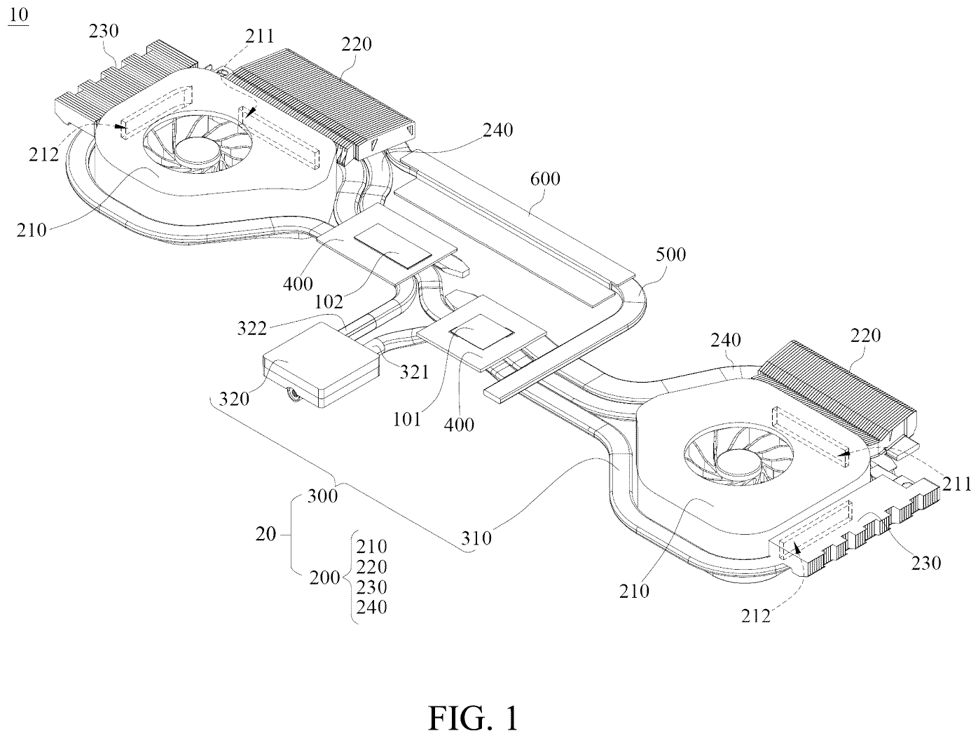

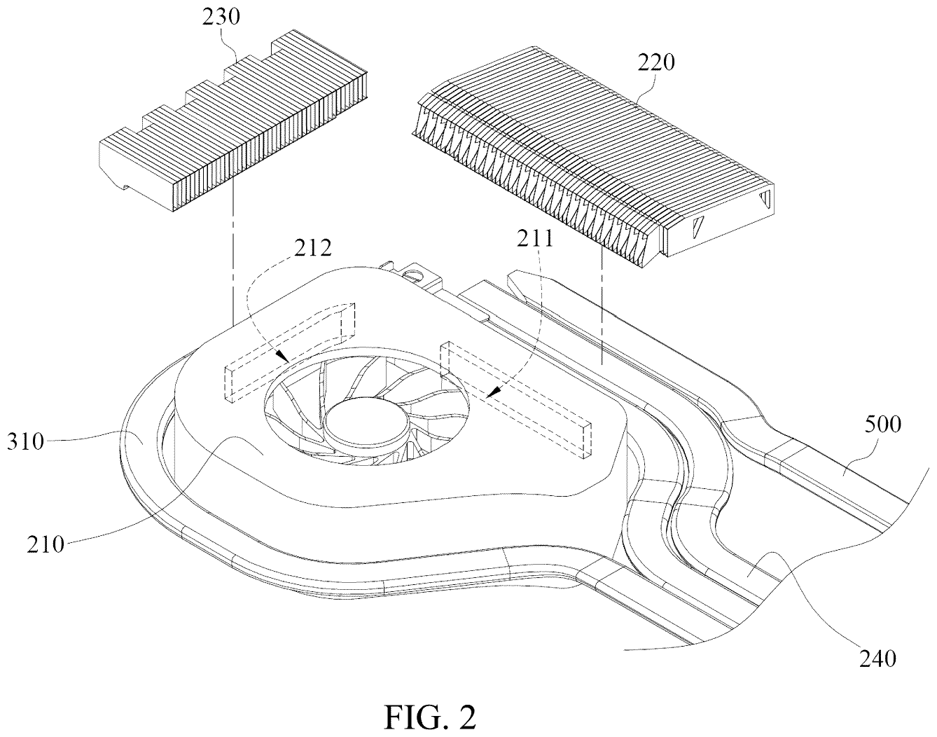

Please refer to FIGS. 1 and 2. FIG. 1 is a perspective view of an electronic device 10 according to an embodiment of the disclosure. FIG. 2 is an exploded schematic view of the air-cooling heat dissipation assembly 200 in FIG. 1.

In this embodiment, the electronic device 10 includes two heat sources 101 and 102, two air-cooling heat dissipation assemblies 200 with two air-cooling heat dissipation devices, and one liquid-cooling heat dissipation assembly 300, where one air-cooling heat dissipation assembly 200 and one liquid-cooling heat dissipation assembly 300 together form a composite heat dissipation mechanism.

In this embodiment, the heat sources 101 and 102 may be, for example, a central processing unit (CPU) or a graphics processing unit (GPU), but are not limited thereto. In other embodiments, the heat sources may include expansion cards, resistors, capacitors, or other electronic components.

The air-cooling heat dissipation assembly 200 includes an airflow generator 210, a first heat dissipation fin 220, and a second heat dissipation fin 230. The airflow generator 210 may be, for example, a centrifugal fan with dual air outlets. The airflow generator 210 has a first air outlet 211 and a second air outlet 212, which are oriented in different directions. The first heat dissipation fin 220 is disposed adjacent to the first air outlet 211 and is thermally coupled to the heat sources 101 and 102. The second heat dissipation fin 230 is disposed adjacent to the second air outlet 212.

The air-cooling heat dissipation assembly 200 may further include a first heat pipe 240. One end of the first heat pipe 240 is thermally coupled to the first heat dissipation fin 220, while the other end is thermally coupled to the heat sources 101 and 102, allowing heat to be transferred from the heat sources 101 and 102 to the first heat dissipation fin 220 for dissipation.

In this embodiment, the liquid-cooling heat dissipation assembly 300 includes a heat-conducting flow pipe 310 and a fluid driver 320. The fluid driver 320 has an outlet 321 and an inlet 322. The heat-conducting flow pipe 310 is in communication with the fluid driver 320 to form a circulation flow path, thereby allowing the cooling fluid to circulate within the circulation flow path.

The heat-conducting flow pipe 310 may be disposed surrounding the airflow generator 210 and thermally coupled to the first heat dissipation fin 220, the second heat dissipation fin 230, and the heat sources 101 and 102. Through this configuration, heat generated by the heat sources 101 and 102 can be transferred to the first heat dissipation fin 220 and the second heat dissipation fin 230 for dissipation.

The heat-conducting flow pipe 310 may be made of thermally conductive materials such as copper or aluminum, but is not limited thereto. In other embodiments, the heat-conducting flow pipe 310 may be made of any material with excellent thermal conductivity.

The first heat dissipation fin 220 and the second heat dissipation fin 230 may have a plate-shaped structure but are not limited thereto. In other embodiments, the first heat dissipation fin 220 and the second heat dissipation fin 230 may have an arc-shaped or needle-shaped structure, depending on thermal performance requirements.

In this embodiment, two heat sources 101 and 102, and two air-cooling heat dissipation assemblies 200 with two air-cooling heat dissipation devices are included. However, the disclosure is not limited to this configuration. In other embodiments, the number of heat sources and air-cooling heat dissipation assemblies may be one, three, or more.

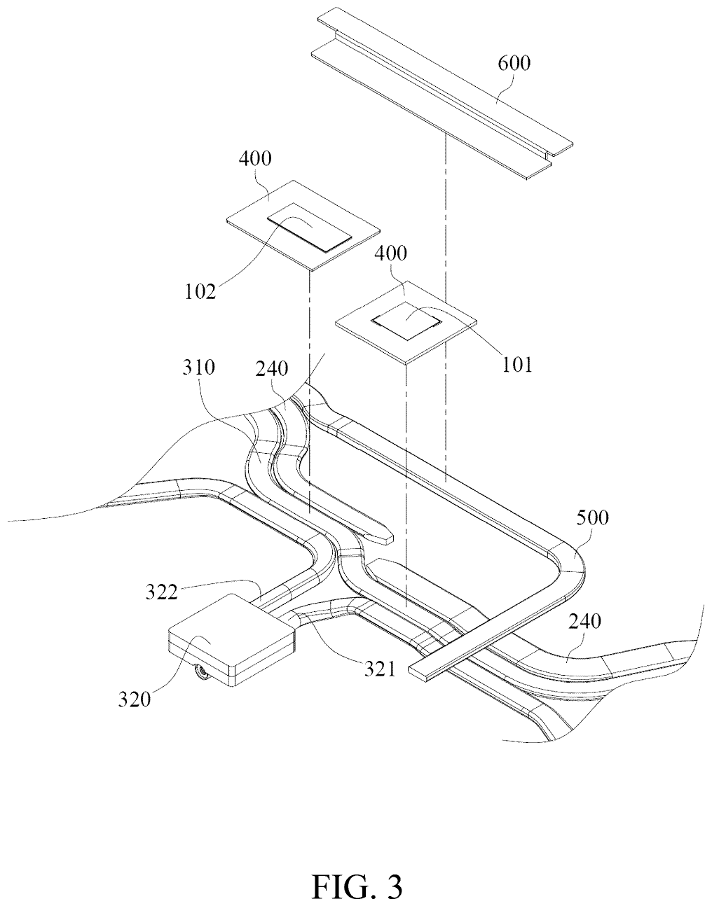

Please refer to FIG. 3. FIG. 3 is an exploded schematic view of the heat source region in FIG. 1. In this embodiment, the electronic device 10 further includes two mounting brackets 400. The two mounting brackets 400 secure the heat sources 101 and 102, enabling thermal coupling between the heat sources 101 and 102, the first heat pipe 240, and the heat-conducting flow pipe 310.

The electronic device 10 may further include a second heat pipe 500 and a fixing bracket 600. One end of the second heat pipe 500 is thermally coupled to one of the first heat dissipation fins 220, while the other end is thermally coupled to the heat source 101. Through this configuration, heat generated by the heat source 101 can be transferred to the first heat dissipation fin 220 for dissipation, thereby further enhancing heat dissipation efficiency. The fixing bracket 600 secures the second heat pipe 500 and the heat source 101.

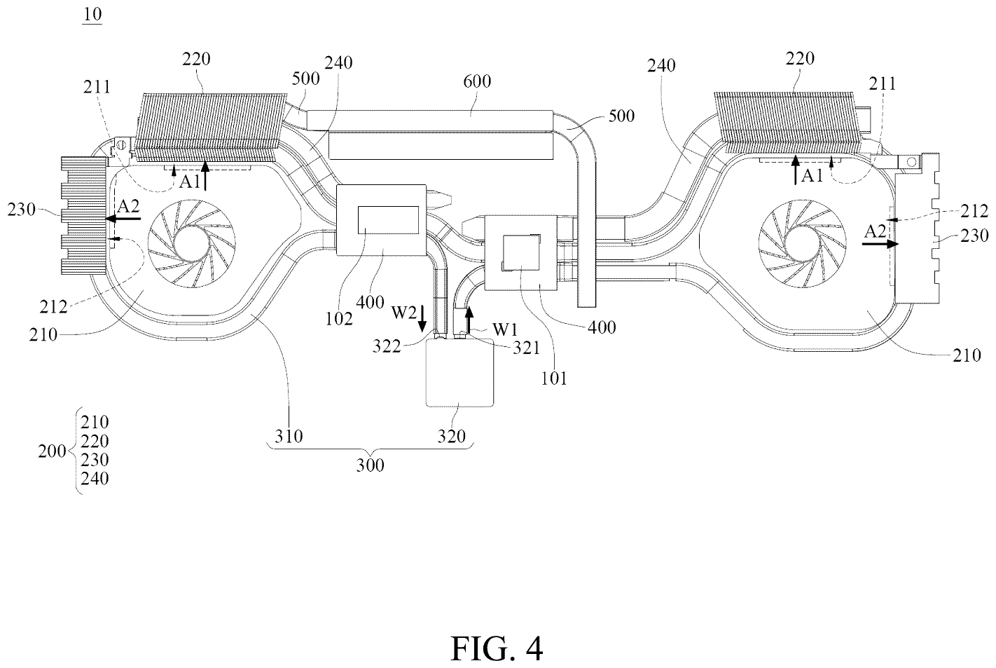

Please refer to FIG. 4. FIG. 4 is a schematic diagram illustrating the heat dissipation paths of the electronic device 10 in FIG. 1. In this embodiment, the airflow generated by the airflow generator 210 flows through the first air outlet 211 in direction Al toward the first heat dissipation fin 220. The first heat dissipation fin 220 facilitates heat dissipation from the first heat pipe 240, the heat-conducting flow pipe 310, and the second heat pipe 500. Additionally, airflow is discharged through the second air outlet 212 in direction A2 toward the second heat dissipation fin 230, allowing the second heat dissipation fin 230 to dissipate heat from the heat-conducting flow pipe 310.

Meanwhile, the fluid driver 320 drives the cooling fluid to flow in direction W1, causing the cooling fluid to first enter the heat-conducting flow pipe 310 through the outlet 321 and flow toward the heat source 101 to absorb heat generated by the heat source 101. After absorbing heat, the cooling fluid sequentially flows through the second heat dissipation fin 230 and the first heat dissipation fin 220, where the heat absorbed from the heat source 101 is dissipated. In other words, the cooling fluid first removes heat from the heat source 101 and then releases it through the second heat dissipation fin 230 and the first heat dissipation fin 220.

Subsequently, the cooling fluid continues to flow through the heat-conducting flow pipe 310, sequentially passing through the heat source 101 and the heat source 102 to absorb their heat. This means that the cooling fluid undertakes a second heat absorption process at the heat source 101 before absorbing heat from the heat source 102. After absorbing heat from the heat source 102, the cooling fluid sequentially flows through another first heat dissipation fin 220 and the second heat dissipation fin 230, thereby releasing heat once again. Finally, after completing the second heat dissipation cycle for the heat source 102, the cooling fluid returns to the fluid driver 320 via the inlet 322 along direction W2.

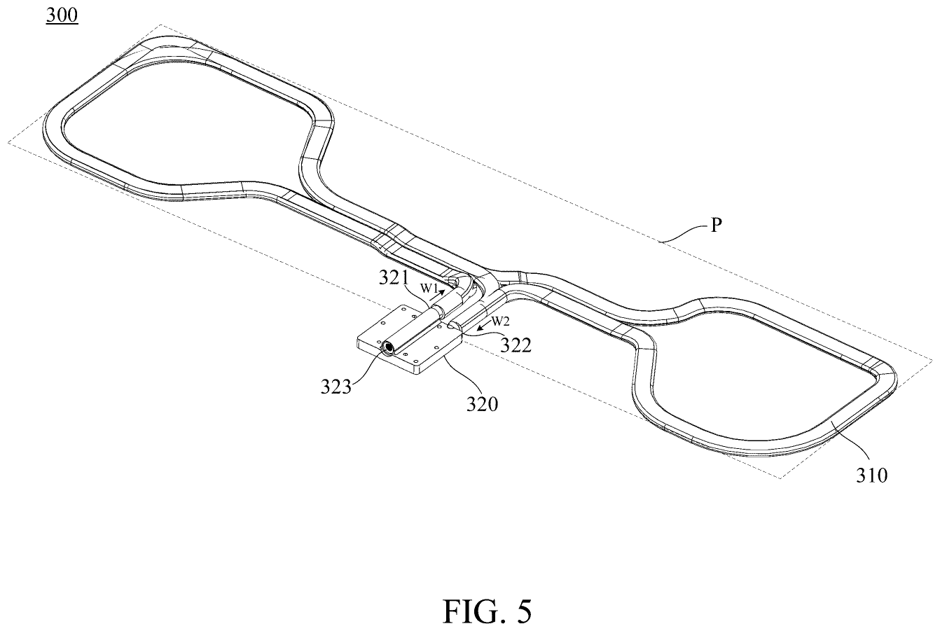

Please refer to FIG. 5. FIG. 5 is a perspective view of the liquid-cooling heat dissipation assembly 300 in FIG. 1. The liquid-cooling heat dissipation assembly 300 includes a heat-conducting flow pipe 310 that is thermally coupled to heat sources and is configured to accommodate a cooling fluid. Additionally, the liquid-cooling heat dissipation assembly 300 includes a fluid driver 320 that is in fluid communication with the heat-conducting flow pipe 310. The fluid driver is designed to circulate the cooling fluid through a fluid outlet 321 and a fluid inlet 322, the flow direction WI of the cooling fluid from the fluid outlet 321 differs from the flow direction W2 of the cooling fluid to the fluid inlet 322. This design enhances the circulation efficiency and optimizes heat dissipation performance. In some implementations, the flow direction W2 of the cooling fluid to the fluid inlet 322 is opposite to the flow direction W1 of the cooling fluid from the fluid outlet 321.

In certain embodiments, the fluid outlet 321 and the fluid inlet 322 are positioned on the same side of the fluid driver 320, simplifying the structural arrangement and facilitating integration with other cooling components, but it is not limited thereto.

In certain embodiments, the heat-conducting flow pipe 310 defines a placement plane P, at least one of the fluid outlet 321 and the fluid inlet 322 is positioned outside of the placement plane P. This configuration helps improve fluid dynamics, optimize the performance of the cooling assembly, and avoid inference of the inlet and outlet of the fluid.

In certain embodiments, the fluid driver 320 may include a driver port 323 for controlling the amount of cooling fluid within the liquid-cooling heat dissipation assembly 300. In some embodiments, the driver port 323 is in fluid communication with the fluid outlet 321, providing for precise control over cooling fluid and successfully regulating heat dissipation in electronic devices through optimal cooling fluid circulation and flow management.

In the above embodiments, the composite heat dissipation mechanism and electronic device utilize the circulation flow path of the liquid-cooling heat dissipation assembly to provide multiple cooling cycles for the heat sources, whereas the air-cooling heat dissipation assembly dissipates heat from both the heat sources and the heat-conducting flow pipe. This significantly improves heat dissipation efficiency for multiple heat sources in electronic devices, addressing the cooling needs of such devices.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A composite heat dissipation mechanism for dissipating heat from heat sources, the composite heat dissipation mechanism comprising:
an air-cooling heat dissipation assembly, including:
an airflow generator having a first air outlet; and
a first heat dissipation fin disposed adjacent to the first air outlet of the airflow generator and thermally coupled to the heat sources; and
a liquid-cooling heat dissipation assembly, including:
a heat-conducting flow pipe thermally coupled to the first heat dissipation fin and configured to accommodate a cooling fluid; and
a fluid driver in communication with the heat-conducting flow pipe to form a circulation flow path and configured to drive the cooling fluid to circulate within the circulation flow path.

2. The composite heat dissipation mechanism of claim 1, wherein the air-cooling heat dissipation assembly further comprises a heat pipe, wherein a first end of the heat pipe is thermally coupled to the first heat dissipation fin, and wherein a second end of the heat pipe is thermally coupled to the heat sources.

3. The composite heat dissipation mechanism of claim 1, wherein the heat-conducting flow pipe is thermally coupled to the heat sources.

4. The composite heat dissipation mechanism of claim 1, wherein the airflow generator has a second air outlet, wherein the second air outlet being oriented in a direction different from that of the first air outlet, and wherein the air-cooling heat dissipation assembly further comprises a second heat dissipation fin located adjacent to the second air outlet.

5. The composite heat dissipation mechanism of claim 4, wherein the heat-conducting flow pipe is thermally coupled to the second heat dissipation fin.

6. The composite heat dissipation mechanism of claim 1, wherein the heat-conducting flow pipe is arranged surrounding the airflow generator.

7. An electronic device comprising:
at least one heat source group;
at least one air-cooling heat dissipation assembly, including:
an airflow generator having a first air outlet, and
a first heat dissipation fin located adjacent to the first air outlet of the airflow generator and thermally coupled to the heat source group; and
a liquid-cooling heat dissipation assembly, including:
a heat-conducting flow pipe thermally coupled to the first heat dissipation fin and configured to accommodate a cooling fluid, and
a fluid driver in communication with the heat-conducting flow pipe to form a circulation flow path and configured to drive the cooling fluid to circulate within the circulation flow path.

8. The electronic device of claim 7, wherein the air-cooling heat dissipation assembly further comprises at least one first heat pipe, and wherein a first end of the first heat pipe is thermally coupled to the first heat dissipation fin and a second end of the first heat pipe is thermally coupled to the heat source group.

9. The electronic device of claim 8, wherein the heat source group includes two heat sources, wherein the air-cooling heat dissipation assembly includes two air-cooling heat dissipation devices, and wherein the first end of the first heat pipe of each of the two air-cooling heat dissipation devices is respectively thermally coupled to the two heat sources while the second end of the first heat pipe of each of the two air-cooling heat dissipation devices is respectively thermally coupled to the first heat dissipation fin of each of the two air-cooling heat dissipation devices.

10. The electronic device of claim 8, wherein the air-cooling heat dissipation assembly further comprises a second heat pipe, and wherein a first end of the second heat pipe is thermally coupled to one of the first heat dissipation fin and a second end of the second heat pipe is thermally coupled to the heat source group.

11. The electronic device of claim 7, wherein the heat-conducting flow pipe is thermally coupled to the heat source group.

12. The electronic device of claim 7, wherein the airflow generator has a second air outlet being oriented in a direction different from that of the first air outlet, and wherein the air-cooling heat dissipation assembly further comprises a second heat dissipation fin located adjacent to the second air outlet.

13. The electronic device of claim 12, wherein the heat-conducting flow pipe is thermally coupled to the second heat dissipation fin.

14. The electronic device of claim 7, wherein the heat-conducting flow pipe is arranged surrounding the airflow generator.

15. A liquid-cooling heat dissipation assembly, comprising:
a heat-conducting flow pipe thermally coupled to a heat source and configured to accommodate a cooling fluid; and
a fluid driver in fluid communication with the heat-conducting flow pipe and configured to circulate the cooling fluid by a fluid outlet and a fluid inlet;
wherein a flow direction of the cooling fluid from the fluid outlet and a flow direction of the cooling fluid to the fluid inlet are different.

16. The liquid-cooling heat dissipation assembly of claim 15, wherein the flow direction of the cooling fluid to the fluid inlet and the flow direction of the cooling fluid from the fluid outlet are opposite.

17. The liquid-cooling heat dissipation assembly of claim 15, wherein the fluid outlet and the fluid inlet are located on the same side of the fluid driver.

18. The liquid-cooling heat dissipation assembly of claim 15, wherein the heat-conducting flow pipe defines a placement plane, and wherein at least one of the fluid outlet and the fluid inlet is not located within the placement plane.

19. The liquid-cooling heat dissipation assembly of claim 15, wherein the fluid driver further comprises a driver port for controlling an amount of the cooling fluid.

20. The liquid-cooling heat dissipation assembly of claim 19, wherein the driver port is in fluid communication with the fluid outlet.
